(19) United States
(12) Patent Application Publication
(10) Pub. No.: US 2015/0331331 A1
(43) Pub. Date: Nov. 19, 2015

(54) DETECTION APPARATUS, LITHOGRAPHY APPARATUS, AND ARTICLE MANUFACTURING METHOD

(71) Applicant: CANON KABUSHIKI KAISHA, Tokyo (JP)

(72) Inventors: Koichi Sentoku, Tokyo (JP); Wataru Yamaguchi, Utsunomiya-shi (JP); Toshihiko Nishida, Utsunomiya-shi (JP); Hideki Ina, Tokyo (JP)

(21) Appl. No.: 14/710,882

(22) Filed: May 13, 2015

(30) Foreign Application Priority Data
May 19, 2014 (JP) 2014-102990

(51) Int. Cl. G03F 7/20; G01B 11/14

(52) U.S. Cl. CPC G03F 7/70191; G01B 11/14

(57) ABSTRACT

Provided is a detection apparatus that detects a mark with a periodic structure and includes an illumination optical system configured to irradiate light on the mark; a light receiving optical system configured to receive a diffracted light from the mark when a relative position between the illumination optical system and the mark is changed in the measurement direction; and a photodetector configured to detect the diffracted light from the light receiving optical system. Here, a numerical aperture of the light receiving optical system in the measurement direction is larger than a numerical aperture of the light receiving optical system in the non-measurement direction in the plane on which the mark is formed.

### BACKGROUND OF THE INVENTION

1. Field of the Invention

The present invention relates to a detection apparatus, a lithography apparatus, and an article manufacturing method.

2. Description of the Related Art

An exposure apparatus is used in a lithography step included in manufacturing steps for semiconductor devices, liquid crystal display devices, and the like. The exposure apparatus is an apparatus that transfers the pattern formed on an original (reticle or the like) to a substrate (e.g., a wafer, a glass plate, or the like where a resist layer is formed on the surface thereof) via a projection optical system. Such an exposure apparatus performs exposure after an alignment measurement system (detection apparatus) installed therein aligns the position of the patterned area present on a substrate with the position of the pattern formed on the original. For example, upon alignment measurement in a semiconductor exposure apparatus, a method for irradiating a mark (alignment mark) formed on a wafer with illumination light to detect light diffracted from the mark using a photoelectric conversion element is employed. However, the measurement method may not achieve highly-accurate measurement if the shape of the optical image of the detected mark is distorted or the contrast of a measurement signal (alignment signal) which is a signal waveform output from the photoelectric conversion element is deteriorated. Thus, Japanese Patent Laid-Open No. 2001-44105 discloses a semiconductor apparatus that generates diffracted light by arranging a mark in a dot pattern and controls the light intensity of measurement light generated in a dot patterned area so as to improve the image forming performance of the optical image of the mark. Japanese Patent No. 3448673 discloses a projection exposure apparatus that employs the TTL-type alignment measurement system and passes the diffracted light generated from the mark as in Japanese Patent Laid-Open No. 2001-44105 through the outside of the range of the optical filter installed in the optical path so as to improve the image forming performance of the optical image of the mark. In contrast, Japanese Patent Laid-Open No. 2011-9259 discloses a semiconductor apparatus in which a mark is segmented so as to obtain a desired measurement accuracy while meeting the etching rate of the circuit pattern exposed on a wafer and the mark or the condition for equalizing a polished amount of CMP.

Here, in response to the technique disclosed in Japanese Patent Laid-Open No. 2001-44105 and Japanese Patent No. 3448673, assume the case where the etching rate or the polished amount of CMP considered in Japanese Patent Laid-Open No. 2011-9259 is equalized. If an attempt is made to equalize the etching rate or the like by the above techniques, the step between the area in which a mark (pattern) is formed on a wafer and the area in which no mark (pattern) is formed becomes small through the CMP process or the like. If the step therebetween becomes small, a difference in light intensity of measurement light between two areas also becomes small. Thus, even if the above technique is employed, the contrast of a measurement signal may be deteriorated. Since the intensity of reflected light is decreased due to interference between reflected light generated from the surface of the resist and reflected light generated from the mark depending on the relationship between a step difference in the mark and a thickness of a resist coated on the mark, the contrast of a measurement signal may be deteriorated also in this case.

### SUMMARY OF THE INVENTION

The present invention provides a detection apparatus which is advantageous for improving, for example, the measurement accuracy.

According to an aspect of the present invention, a detection apparatus that detects a mark with a periodic structure is provided that includes an illumination optical system configured to irradiate light on the mark; a light receiving optical system configured to receive a diffracted light from the mark when a relative position between the illumination optical system and the mark is changed in the measurement direction; and a photodetector configured to detect the diffracted light from the light receiving optical system, wherein a numerical aperture of the light receiving optical system in the measurement direction is larger than a numerical aperture of the light receiving optical system in the non-measurement direction in the plane on which the mark is formed.

Further features of the present invention will become apparent from the following description of exemplary embodiments with reference to the attached drawings.

### BRIEF DESCRIPTION OF THE DRAWINGS

FIG. 1 is a diagram illustrating a configuration of an exposure apparatus including a detection apparatus according to a first embodiment.

FIG. 2 is a diagram illustrating a configuration of the detection apparatus according to the first embodiment.

FIG. 3A is a diagram illustrating the shape of a wafer alignment mark.

FIG. 3B is a diagram illustrating the shape of the segmented mark shown in FIG. 3A.

FIG. 4A is a diagram illustrating the planar shape of the alignment mark shown in FIG. 3A.

FIG. 4B is a diagram illustrating the cross-sectional shape of the alignment mark shown in FIG. 3A.

FIG. 5 is a diagram illustrating the shape of an aperture diaphragm provided in an imaging optical system according to a first embodiment.

FIG. 6A is a diagram illustrating the optical path of measurement light in the imaging optical system according to the first embodiment as viewed from the X-axis direction.

FIG. 6B is a diagram illustrating the optical path of measurement light in the imaging optical system according to the first embodiment as viewed from the Y-axis direction.

FIG. 7 is a graph illustrating the waveform of an alignment measurement signal.

FIG. 8A is a diagram illustrating the shape of a reticle alignment mark.

FIG. 8B is a diagram illustrating the shape of the segmented mark shown in FIG. 8A.

FIG. 9A is a diagram illustrating the optical path of measurement light in an imaging optical system according to a second embodiment as viewed from the X-axis direction.

FIG. 9B is a diagram illustrating the optical path of measurement light in the imaging optical system according to the second embodiment as viewed from the Y-axis direction.

FIG. 10 is a diagram illustrating a configuration of a detection apparatus according to a third embodiment.

FIG. 11A is a diagram illustrating the optical path of measurement light in a light receiving optical system according to a third embodiment as viewed from the X-axis direction.

FIG. 11B is a diagram illustrating the optical path of measurement light in the light receiving optical system according to the third embodiment as viewed from the Y-axis direction.

### DESCRIPTION OF THE EMBODIMENTS

Hereinafter, preferred embodiments of the present invention will be described with reference to the drawings.

### First Embodiment

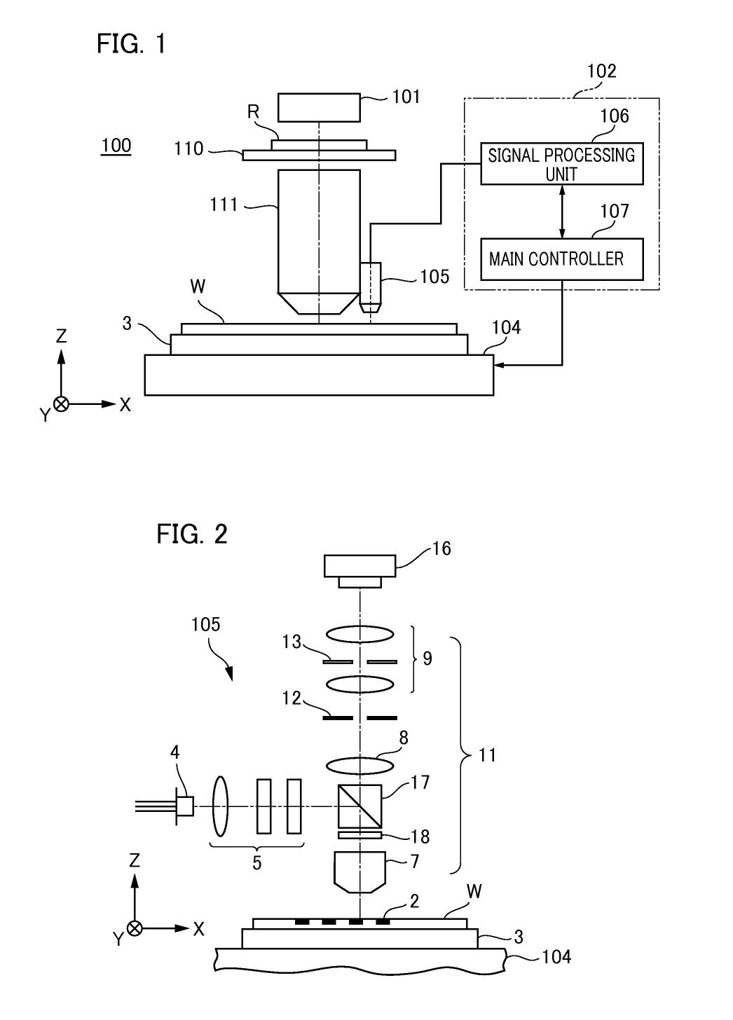

Firstly, a description will be given of a detection apparatus according to a first embodiment of the present invention and an exposure apparatus including the detection apparatus. FIG. 1 is a schematic diagram illustrating a configuration of an exposure apparatus 100 according to the present embodiment. For example, the exposure apparatus 100 is a projection type exposure apparatus that is used in a lithography step included in manufacturing steps of semiconductor devices and exposes (transfers) a pattern formed on a reticle R by a step-and-scan method to a wafer W (a substrate). In FIG. 1, a description will be given where the Z-axis is aligned parallel to the optical axis of a projection optical system 111, the X-axis is aligned in the scanning direction (a relative moving direction between the reticle R and the wafer W) of the wafer W during exposure within the same plane perpendicular to the Z-axis, and the Y-axis is aligned in the non-scanning direction perpendicular to the X-axis. The exposure apparatus 100 includes an illumination system 101, a reticle stage 110, a projection optical system 111, a wafer stage 104, an alignment measurement system 105, and a controller 102.

The illumination system 101 adjusts light emitted from a light source (laser light source) (not shown) to illuminate the reticle R. The reticle R is an original made of, for example, quartz glass, on which a pattern (e.g., circuit pattern) to be transferred onto the wafer W is formed. The reticle stage 110 is movable in X- and Y-axis directions while holding the reticle R. The projection optical system 111 projects light which has passed through the reticle R onto the wafer W with a predetermined magnification (e.g., ½). The wafer W is a substrate consisting of, for example, single crystal silicon, where a resist (sensitizer) is coated on the surface thereof. The wafer stage 104 is movable in X-, Y-, and Z- (ωx, ωy, and ωz which are their respective rotational directions may also be included) axis directions while holding the wafer W via a wafer chuck 3.

FIG. 2 is a schematic diagram illustrating a configuration of the alignment measurement system 105. The alignment measurement system 105 is a detection apparatus in the present embodiment that measures the position of a mark (wafer alignment mark) 2 formed on the wafer W (object) held on the wafer stage 104. A detailed description will be given below of the shape of the mark 2. The mark 2 has two types of marks for measurement in the X-axis direction and for measurement in the Y-axis direction. The alignment measurement system 105 also has two measurement systems (detection systems), i.e., a system for measuring (detecting) the mark 2 for measurement in the X-axis direction and a system for measuring (detecting) the mark 2 for measurement in the Y-axis direction, and two detectors 16 corresponding thereto. Note that the measurement principles by these two measurement systems are basically the same. Thus, a description will be given below of the mark 2 for measurement in the X-axis direction and the measurement system for measuring the mark 2 for ease of explanation.

The alignment measurement system 105 has an illumination optical system 5, an imaging optical system (light receiving optical system) 11, and a detector 16. A part of the imaging optical system 11 also serves as the illumination optical system 5. The illumination optical system 5 includes, for example, a cylindrical lens and irradiates the mark 2 on the wafer W with light emitted from the light source 4, which serves as illumination light for alignment measurement, via a PBS (Polarizing Beam Splitter) 17 and a λ/4 plate 18 (illuminates light on the mark 2). The imaging optical system 11 includes an objective lens 7, a λ/4 plate 18, a PBS 17, a relay lens 8, a field diaphragm 12, an elector lens 9, and an aperture diaphragm 13. The imaging optical system 11 receives the optical image (measurement light including reflected light, diffracted light, or scattered light) of the mark 2, which has been generated by irradiation of illumination light by the illumination optical system 5, and images the optical image on the detection surface of the detector 16 with a predetermined magnification (e.g., 100). Here, the detector (photodetector) 16 is a photoelectric conversion element (photoelectric converter) such as a CCD sensor or a photodiode. Note that a detailed description will be given below of the shape of the aperture diaphragm 13. The alignment measurement system 105 measures measurement light (detected by the detector 16) while changing a relative position between the alignment measurement system 105 and the mark 2 for measurement in the X-axis direction (a relative position between the illumination optical system 5 and the mark 2) in the X-axis direction (e.g., while scanning the wafer stage 104 with respect to the alignment measurement system 105). The detector 16 outputs the obtained measurement signal (alignment signal) to a signal processing unit 106.

The controller 102 includes a main controller 107 and a signal processing unit 106. The main controller 107 is constituted, for example, by a computer or the like and is connected to the components of the exposure apparatus 100 via a line to thereby supervise the operation of the components in accordance with a program or the like. The signal processing unit 106 determines the position of the mark 2 based on the measurement signal obtained from the detector 16 of the alignment measurement system 105, and transmits the result to the main controller 107. The main controller 107 controls the operation of the wafer stage 104 during exposure with use of the position result obtained from the signal processing unit 106 as control data for the wafer stage 104. Note that the controller 102 may be integrated with the rest of the exposure apparatus 100 (provided in a shared housing) or may also be provided separately from the rest of the exposure apparatus 100 (provided in a separate housing). The signal processing unit 106 may also be provided separately from the controller 102 as the component of the alignment measurement system 105 so as to be connected to the controller 102 via a line.

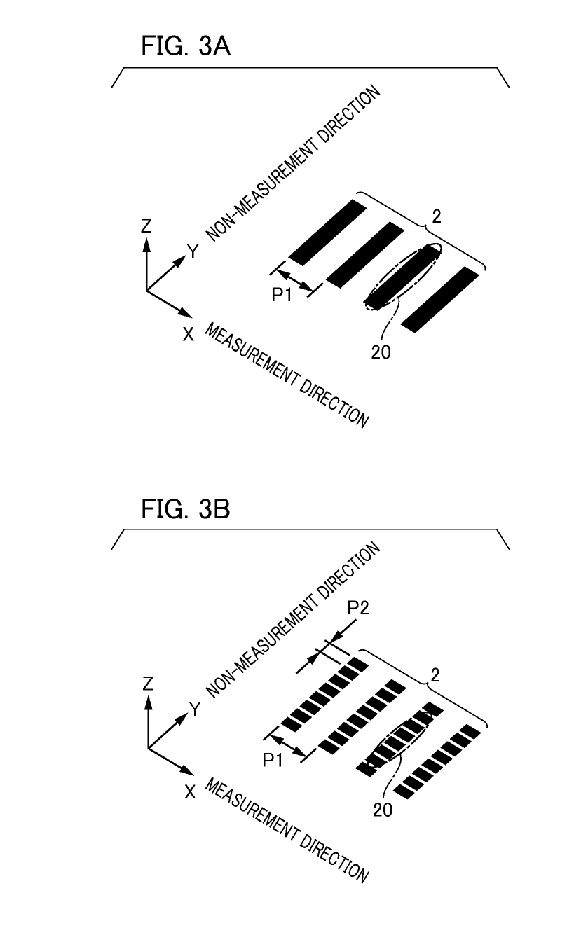

Next, a description will be given of the shape of the mark 2. While a description will be given below of the mark 2 for measurement in the X-axis direction, the same applies to the mark 2 for measurement in the Y-axis direction. FIGS. 3A and 3B are perspective views illustrating the shape of the mark 2. Among them, FIG. 3A is a diagram illustrating a first example of the shape of the mark 2 with a periodic structure which is constituted by a plurality of (in the present embodiment, four) line-and-space patterns. In FIG. 3A, the patterns shown by solid lines are juxtaposed periodically at a pitch P1 in the X-axis direction on a part of the wafer W. The shape (irradiation area) of illumination light to be illuminated on the mark 2 using the illumination optical system 5 is elliptical as shown by illumination light 20 in FIG. 3A, where the X-axis direction represents the short axis and the Y-axis direction represents the long axis.

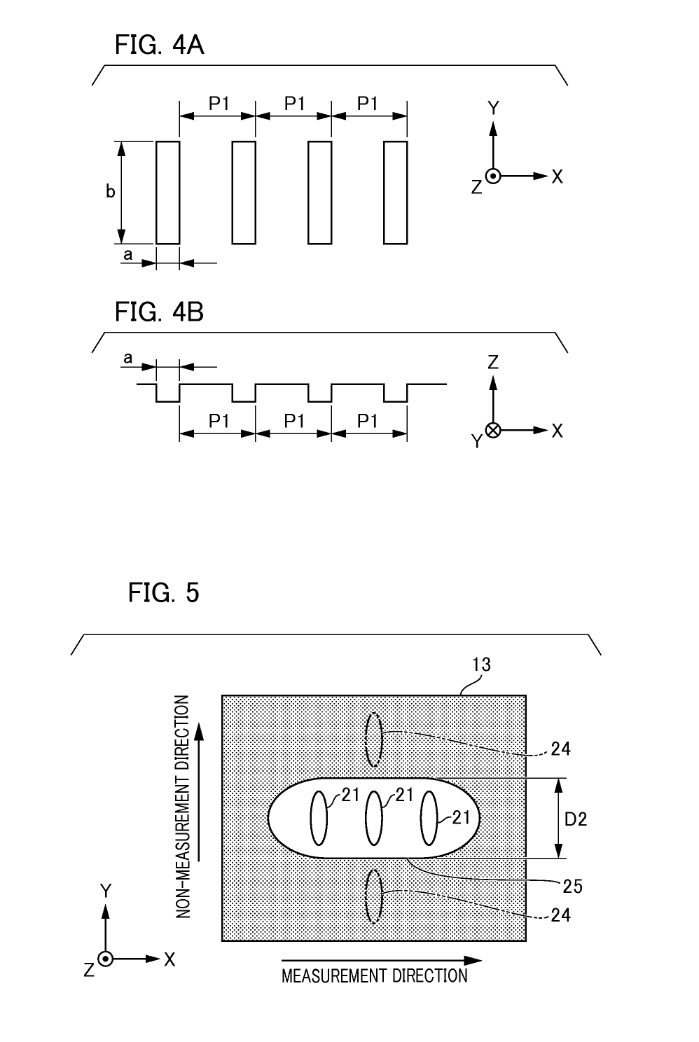

FIGS. 4A and 4B are diagrams illustrating the planar shape and the cross-sectional shape of the mark 2 shown in FIG. 3A, respectively. As shown in FIG. 4A, a single pattern is a rectangular mark with the size of a width “a” of 4 pm in the X-axis direction serving as the measurement direction and of a length “b” of 30 μm in the Y-axis direction serving as the non-measurement direction, where four patterns are lined up with the pitch P1 of 20 μm in the X-axis direction. As shown in FIG. 4B, the cross-sectional shape of each pattern is a concave formed by etching. Note that, in practice, a resist (not shown) is coated on the mark 2 prior to exposure.

FIG. 3B is a diagram illustrating a second example of the shape of the mark 2 with a periodic structure which is constituted by a plurality of patterns, where a single pattern as shown in FIG. 3A is further segmented. In FIG. 3B, the patterns shown by solid lines are juxtaposed periodically at the first pitch P1 in the X-axis direction and at a second pitch (segment pitch) P2 in the Y-axis direction on a part of the wafer W. In this case, it is preferable that the line width of one area (solid area) which constitutes a pattern segmented in the Y-axis direction is less than three times of the minimum line width of the one area in the X-axis direction. The shape of illumination light to be illuminated on the mark 2 using the illumination optical system 5 is elliptical as shown by the illumination light 20 in FIG. 3B. More specifically, the size of the illumination light 20 in the X-axis direction is set to be smaller than the pitch P1 such that the diffracted light is not generated from the mark 2 in the X-axis direction including the X-Z plane but only reflected light is generated from the mark 2 upon reception of the illumination light 20. On the other hand, the size of the illumination light 20 in the Y-axis direction is large enough to irradiate a plurality of solid areas such that the diffracted light is generated from the mark in the Y-axis direction upon reception of the illumination light 20. Hereinafter, the second example shown in FIG. 3B is represented by “segmented mark 2” and the first example shown in FIG. 3A is represented by “non-segmented mark 2” for convenience.

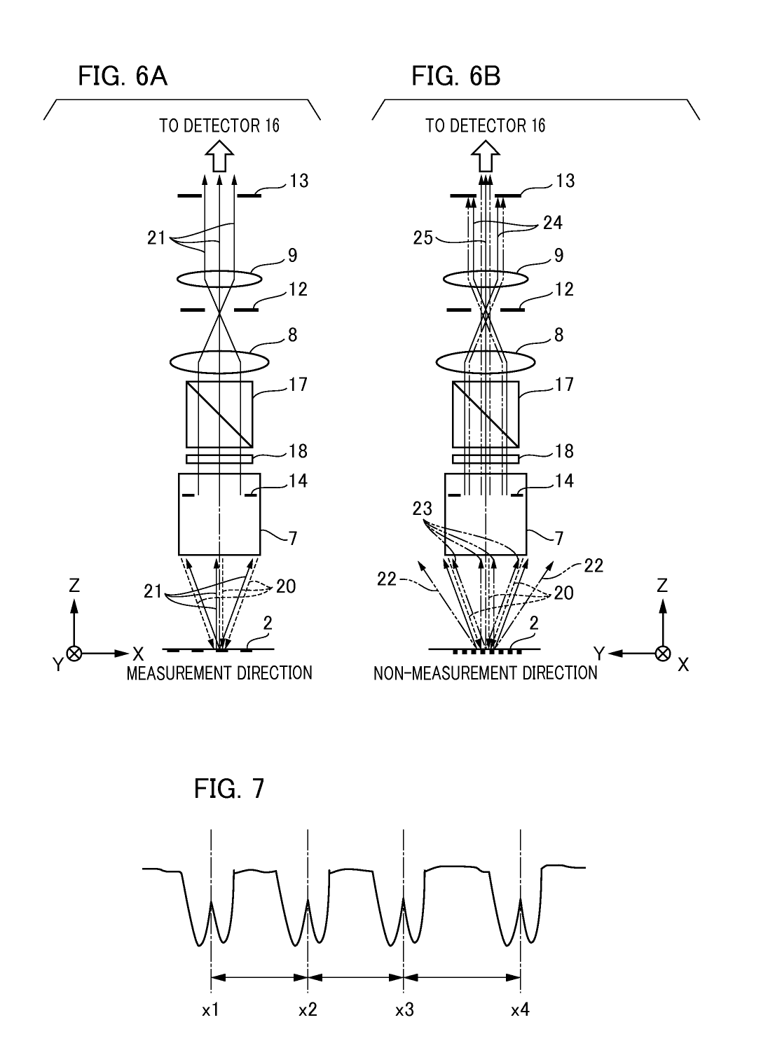

Next, a description will be given of the shape of the aperture diaphragm 13. FIG. 5 is a diagram illustrating the planar shape of the aperture diaphragm 13 as viewed from the detector 16 side. FIGS. 6A and 6B are schematic diagrams each illustrating the optical path of measurement light, which indicates chief rays of reflected light and diffracted light generated from the segmented mark 2 shown in FIG. 3B, in the imaging optical system 11. Among them, FIG. 6A is a diagram illustrating the imaging optical system 11 as viewed from the X-axis direction which is the measurement direction and FIG. 6B is a diagram illustrating the imaging optical system 11 as viewed from the Y-axis direction which is the non-measurement direction. The scattered light generated at the edge of the mark 2 is negligible because the amount of light is very small.

Firstly, as shown in FIG. 6A, measurement light 21 (including diffracted light) which is reflected from the mark 2 upon reception of the illumination light 20 illuminated within the range of the NA (numerical aperture) of the objective lens 7 is captured within the range of the NA of the objective lens 7 and then is directed to the detector 16 via the imaging optical system 11. Thus, the shape of the aperture formed in the aperture diaphragm 13 is defined as shown in FIG. 5 such that the first measurement light 21 consisting of specularly reflected light generated from the mark 2 in the X-Z plane direction may be directed to the detector 16 by passing through the aperture.

On the other hand, as shown in FIG. 6B, second measurement light generated from the mark 2 in the Y-axis direction including the Y-Z plane upon reception of the illumination light 20 is divided into two types. The first one is second A measurement light 22 which travels outside the range of the NA of the objective lens 7. The second one is second B measurement light 23 which falls within the range of the NA of the objective lens 7. The second B measurement light 23 is further divided into second B₁ measurement light 24 which is shielded by the aperture diaphragm 13 and second B₂ measurement light 25 which is incident on the detector 16 after being passed through the aperture formed in the aperture diaphragm 13. In the present embodiment, in order to shield a portion of the second B measurement light which is measurement light generated from the mark 2 in the Y-axis direction, the NA of the imaging optical system 11 is defined such that the NA in the Y-axis direction (non-measurement direction) is smaller than that in the X-axis direction (measurement direction). More specifically, the shape of the aperture formed in the aperture diaphragm 13 is elliptical as shown in FIG. 5 and the opening dimension of the aperture diaphragm 13 in the Y-axis direction (D2) is smaller than that in the X-axis direction.

Here, a description will be given of the case where the non-segmented mark 2 as shown in FIG. 3A is measured by the conventional alignment measurement system for comparison. When the mark 2 is scanned in the X-axis direction in the state where the mark 2 is irradiated with the illumination light 20 with reference to FIG. 3A, the detector 16 alternately measures measurement light from the solid patterns and measurement light from an area other than the patterns. FIG. 7 is a graph illustrating a waveform of a measurement signal obtained by measuring the optical image of the mark 2 corresponding to the shape of the mark 2 shown in FIGS. 4A and 4B by the conventional alignment measurement system. Here, it is assumed that the patterns of the mark 2 are configured as recesses as described above and a resist is coated on the wafer W (on the mark 2). At this time, light reflected from the surface of the resist interferes with light reflected from the surface of the mark 2, the light intensity of measurement light from the recesses is equivalent to the light intensity of measurement light from the area other than the patterns depending on the thickness of the resist or a step difference between the recesses and the area other than the patterns. Consequently, a contrast (a contrast between signal intensities from the periodically repeating patterns and the area other than the patterns) of a measurement signal output from the detector is deteriorated, so that the alignment measurement system may not obtain the measurement signal with high accuracy.

Thus, in the present embodiment, the alignment measurement system 105 has the aperture diaphragm 13 as described above. It is further preferable that the segmented mark 2 as shown in FIG. 5 is formed in advance on the wafer W before carrying out the alignment measurement.

Next, a description will be given of the shape of the aperture diaphragm 13 and its operation based on the relationship between diffracted light in plural orders which may be generated from the mark 2 in the X-axis and Y-axis directions and the NA of the objective lens 7. Given that the diffraction angle of diffracted light which may be generated from the mark 2 is “0”, the diffraction order (integer) is “m”, the wavelength of the illumination light 20 is “λ”, and the pitch of the mark 2 is “P”, the following formula (1) is satisfied:

sin θ=m×λ/P (1)

Hereinafter, it is assumed that the NA of the objective lens 7 is 0.4, the pitch P2 of the mark 2 is 1.59 μm, the pitch P1 of the mark 2 is 10.0 μm, and the wavelength λ of the illumination light 20 is 0.632 μm.

Firstly, if the illumination light 20 is normal incidence, the diffraction angle θ1 of diffracted light which may be generated in the Y-axis direction which is the non-measurement direction satisfies the following formula (2) with use of Formula (1):

sin θ1=m×0.632/1.59 (2)

By Formula (2), the diffraction angle of ±first-order diffracted light is ±23.4 degrees, so that only specularly reflected light and ±first-order diffracted light are incident on the objective lens 7. Among the illumination light 20, specularly reflected light and positive first-order diffracted light with respect to illumination light at Full NA (in FIG. 6B, illumination light from diagonally above on the left of the light exiting surface of the objective lens 7) falls within the measurement NA of the objective lens 7. On the other hand, negative first-order diffracted light travels outside the range of the measurement NA of the objective lens 7 and is not directed to the detector 16. The sign of diffracted light is defined such that the order of diffracted light generated in the counter-clockwise direction with respect to specularly reflected light becomes positive.

On the other hand, if the illumination light 20 is normal incidence in the same manner as in the foregoing, the diffraction angle θ2 of diffracted light which may be generated in the X-axis direction which is the measurement direction satisfies the following formula (3) with use of Formula (1):

sin θ2=m×0.632/10.0 (3)

By Formula (3), the objective lens 7 can capture up to ±six-order diffracted light generated in the X-axis direction.

Here, the exit pupil 14 of the objective lens 7 having a diameter of φD1 with respect to the mark 2 with the size as described above is imaged at the position of the aperture diaphragm 13 with the imaging magnification 3. In this case, if the width D2 (see FIG. 5) of the aperture formed in the aperture diaphragm 13 in the Y-axis direction is set to meet the condition expressed by Formula (4), the aperture diaphragm 13 can preferably shield a portion of measurement light generated in the Y-axis direction.

D2<D1×β (4)

In this manner, the light intensity of measurement light incident on the detector 16 after being generated from the patterns (recesses) of the mark 2 becomes less than the light intensity of measurement light generated from the area other than the patterns. Thus, the alignment measurement system 105 obtains a measurement signal with a high contrast value as compared with the conventional alignment measurement system, resulting in an improvement in measurement accuracy.

In the optical image of the mark 2 in the second example in the non-measurement direction, the resolution performance for the segment pitch is below a resolution limit due to a reduction in the measurement NA by the aperture diaphragm 13. Thus, the detector 16 normally measures the mark 2 as an optical image having a uniform light intensity because it cannot distinguish individual segmented pattern. In the alignment measurement system 105, the size of the measurement NA in the measurement direction is set at the Full NA as described above so as not to cause the aperture diaphragm 13 to shield diffracted light. Thus, the detector 16 can obtain an optical image with a sharp rise in its intensity distribution even at the boundary of the gray-level optical image of the mark 2.

The above description has been given by taking an example of the alignment measurement system 105 as the detection apparatus for measuring a mark (wafer alignment mark) 2 on the wafer W. However, the present invention is not limited thereto but may also be applicable to a reticle alignment measurement system for measuring a mark (reticle alignment mark) formed in advance on a reflective reticle which may be employed in, for example, a EUV exposure apparatus. Here, the EUV exposure apparatus is an exposure apparatus that uses light (EUV (Extreme Ultra Violet) light) of the soft X-ray region having a wavelength of from 5 to 15 nm as exposure light, where the minimum line width may be 100 nm. Since the configuration of the reticle alignment measurement system is basically the same as that of the alignment measurement system 105 according to the first embodiment, the same components as those in the first embodiment are designated by the same reference numerals hereinafter.

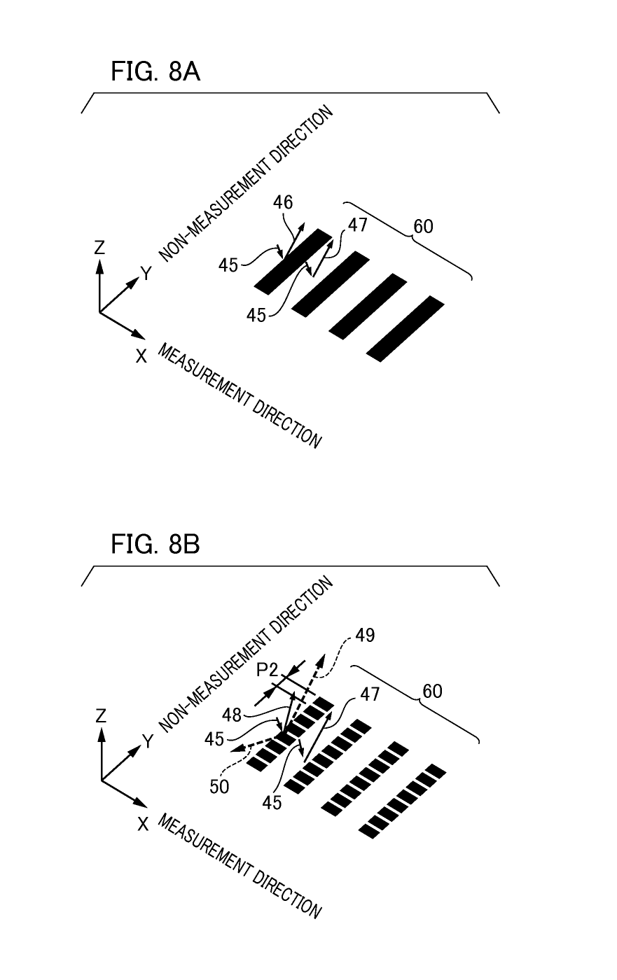

FIGS. 8A and 8B are perspective views illustrating the shape of a mark 60 formed on a reflective reticle and the direction of travel of incident light on and diffracted light from the mark 60. Among them, FIG. 8A is a diagram illustrating a first example of a non-segmented mark having the same shape as that of the mark 2 shown in FIG. 3A in the first embodiment. On the other hand, FIG. 8B is a diagram illustrating a second example of a segmented mark having the same shape as that of the mark 2 shown in FIG. 3B in the first embodiment. The patterns shown by solid lines of the mark 60 are written by, for example, chromium (Cr). In FIGS. 8A and 8B, illumination light is uniformly illuminated over the entire mark 60, and incident light 45 is illustrated as representative light to be illuminated over the Cr area (patterns) and the non-Cr area (the area other than the patterns) for ease of explanation.

Here, on the mark 60 as the first example shown in FIG. 8A, the reflectance (the ratio of the light intensity of the diffracted light 46 to that of the incident light 45) of the Cr area at a wavelength of measurement light is 40% and the reflectance (the ratio of the light intensity of the diffracted light 47 to that of the incident light 45) of an area other than the Cr area is 50%. In contrast, on the mark 60 as the second example shown in FIG. 8B, diffracted light generated from the incident light 45 is not only diffracted light 48 generated on the Z-X plane but also diffracted light 49 and 50 generated on the Y-Z plane. Since the pitch P2 in the Y-axis direction is set such that the diffraction angles of the diffracted light 49 and 50 are larger than the aperture angle of the objective lens 7, the diffracted light 49 and 50 are not incident on the detector 16. Thus, if the shape of the mark 60 is segmented as shown in the second example, the total light intensity of diffracted light which is generated from the Cr area and is incident on the detector 16 decreases as compared with the first example, resulting in a further improvement in signal contrast between the Cr area and the non-Cr area on the detector 16.

As described above, according to the present embodiment, a detection apparatus which is advantageous for improving the measurement accuracy may be provided. An exposure apparatus (lithography apparatus) using the detection apparatus according to the present embodiment may perform alignment measurement with high accuracy.

### Second Embodiment

Next, a description will be given of a detection apparatus according to a second embodiment of the present invention. The alignment measurement system 105 which is the detection apparatus according to the first embodiment uses the aperture diaphragm 13 having an elliptical aperture such that the NA of the imaging optical system in the non-measurement direction becomes smaller than that in the measurement direction so as not to make diffracted light generated from the mark 2 in the non-measurement direction incident on the detector 16. In contrast, a feature of the alignment measurement system which is the detection apparatus according to the present embodiment lies in the fact that the NA of the imaging optical system in the non-measurement direction becomes smaller than that in the measurement direction by changing the outer shape of an optical element (lens) constituting the imaging optical system.

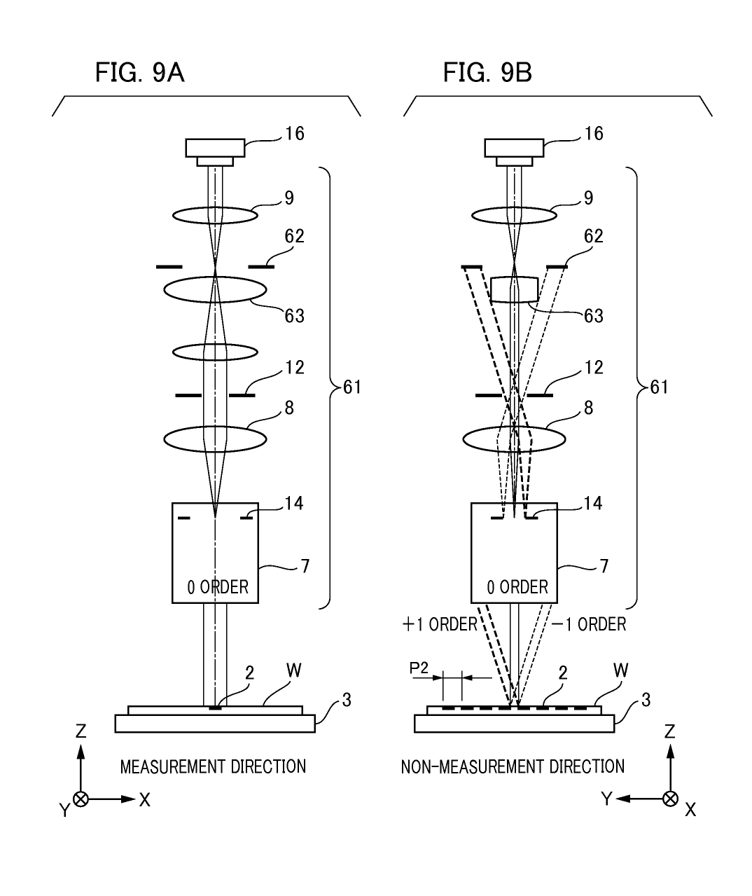

FIGS. 9A and 9B are schematic diagrams each illustrating a configuration of an imaging optical system 61 included in the alignment measurement system serving as the detection apparatus according to the present embodiment with chief rays of reflected light and diffracted light generated from the segmented mark 2 shown in FIG. 3B. Among them, FIG. 9A is a diagram illustrating the imaging optical system 61 as viewed from the X-axis direction which is the measurement direction and FIG. 9B is a diagram illustrating the imaging optical system 61 as viewed from the Y-axis direction which is the non-measurement direction. Note that the same components in the imaging optical system 61 as those in the imaging optical system 11 of the alignment measurement system 105 according to the first embodiment are designated by the same reference numerals, and explanation thereof will be omitted. While the illumination optical system of the alignment measurement system according to the present embodiment is not shown, the illumination optical system is the same as the illumination optical system 5 of the alignment measurement system 105 according to the first embodiment.

In the imaging optical system 61, the aperture shape of an aperture diaphragm 62 corresponding to the aperture diaphragm 13 in first embodiment is circle. Next, the shape of the front lens group of an elector lens 63 (optical element), which is arranged in the vicinity of the aperture diaphragm 62, corresponding to the elector lens 9 in the first embodiment is made such that both ends of the front lens group are notched parallel in the X-axis direction relative to the optical axis so as not to make diffracted light in the non-measurement direction incident on the detector 16. Such a configuration of the alignment measurement system in the present embodiment provides the same effects as those in the first embodiment. The optical element for reducing the NA of the imaging optical system in the non-measurement direction to be smaller than that in the measurement direction is not limited to the elector lens 63 having such a notch but may also be, for example, a cylindrical lens or a toric lens for adjusting the NA.

### Third Embodiment

Next, a description will be given of a detection apparatus according to a third embodiment of the present invention. As is apparent from the fact that the alignment measurement system 105 which is the detection apparatus according to the first embodiment includes the imaging optical system 11, the optical image of the mark 2 is detected by the detector 16. In contrast, a feature of the alignment measurement system according to the present embodiment lies in the fact that the technique in the above embodiments is applied to the alignment measurement system which does not include an imaging optical system but has a light receiving optical system in which only the light intensity from the mark 2 is detected by a detector 44.

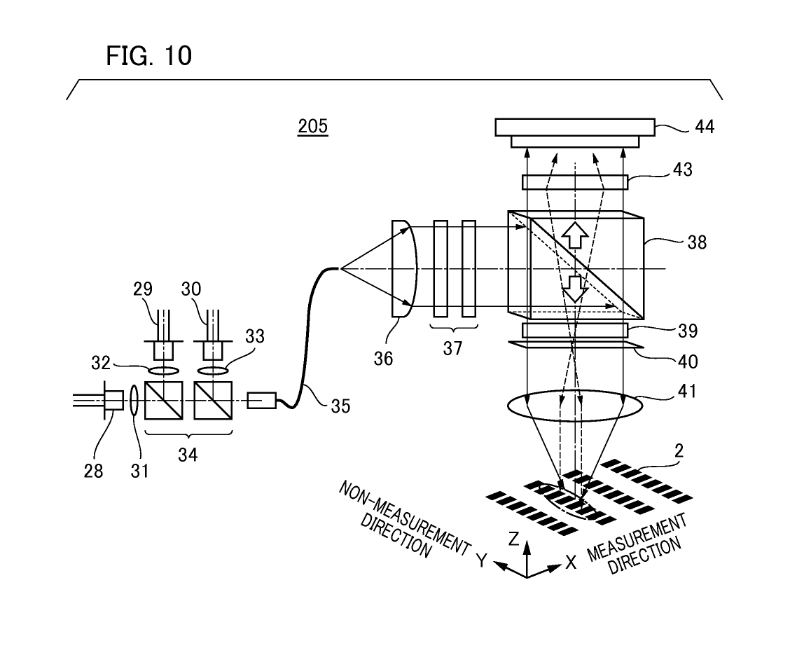

FIG. 10 is a schematic diagram illustrating a configuration of an alignment measurement system 205 which serves as the detection apparatus according to the present embodiment. As in the above embodiments, the alignment measurement system 205 may be installed in the exposure apparatus 100 instead of the alignment measurement system 105. Note that the shape of the mark 2 formed on the wafer W (not shown) is segmented as shown in FIG. 3B in the first embodiment. As in the first embodiment, a description will be given below of the mark 2 for measurement in the X-axis direction and the measurement system for measuring the mark 2.

The alignment measurement system 205 includes a plurality of light sources (e.g., LDs or LEDs) 28, 29, and 30 having different wavelengths from each other, a plurality of collimator lenses 31, 32, and 33 arranged in the respective light sources 28, 29, and 30, a plurality of optical elements, and a detector 44. A plurality of light sources may not be a multi-wavelength light source consisting of a plurality of LDs or LEDs but may be an LD or LED consisting of a single wavelength. Firstly, light emitted by simultaneous selection of all light sources 28, 29, and 30 or selection of one or two light sources is collimated into collimated light by the collimator lenses 31, 32, and 33. A dichroic prism 34 equalizes the collimated light on the same optical axis to make the collimated light incident on a fiber 35 with a collimator lens. Diverging light emitted from the fiber 35 sequentially passes through a collimator lens 36, a cylindrical lens 37, a PBS 38, a λ/4 plate 39, and an aperture diaphragm 40, is converged by an objective lens 41, and then is illuminated on the mark 2. At this time, the shape of illumination light to be illuminated on the mark 2 is elliptical as described in the first embodiment, where the X-axis direction represents the short axis and the Y-axis direction represents the long axis. By a combination of the collimator lens 36, the cylindrical lens 37, and the objective lens 41, converged light is critically illuminated on the wafer W in the X-axis direction and collimated light is Koehler-illuminated on the wafer W in the Y-axis direction. Then, reflected light and diffracted light from the mark 2, which serve as measurement light, sequentially passes through the objective lens 41, the aperture diaphragm 40, the λ/4 plate 39, the PBS 38, and the cylindrical lens 43, and then is measured by a detector (photoelectric conversion element) 44.

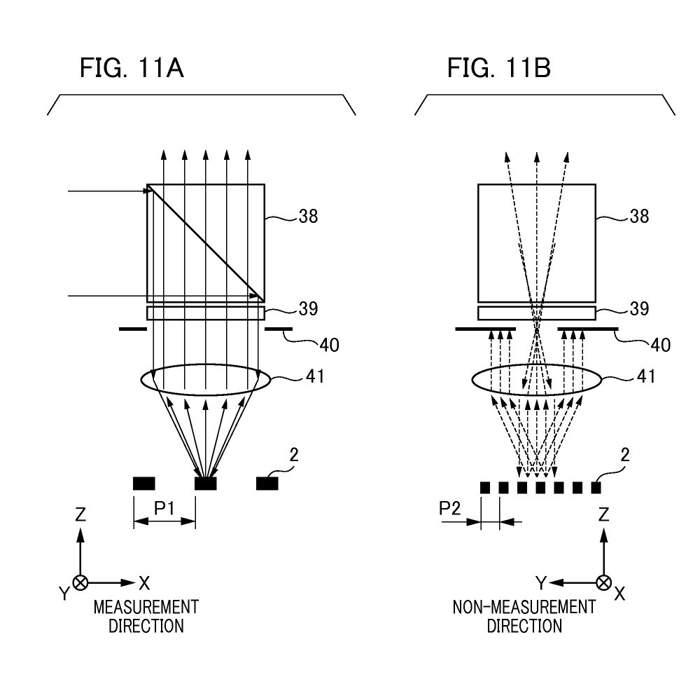

Next, a specific description will be given of the shape of the aperture diaphragm 40 in the alignment measurement system 205. FIGS. 11A and 11B are schematic diagrams each illustrating the optical path of measurement light, which indicates chief rays of reflected light and diffracted light generated from the segmented mark 2 shown in FIG. 3B, in the light receiving optical system. Among them, FIG. 11A is a diagram illustrating the light receiving optical system as viewed from the X-axis direction which is the measurement direction and FIG. 11B is a diagram illustrating the light receiving optical system as viewed from the Y-axis direction which is the non-measurement direction.

Firstly, FIG. 11A shows a state where, after collimated light is incident on the PBS 38, the direction of travel of the collimated light is bent by 90 degrees at the reflection surface and then the collimated light is converged by the objective lens 41 to be critically illuminated on the mark 2. The size of the converged illumination light is set to be smaller than the pitch P1 of the mark 2 such that no diffracted light is generated in the X-axis direction. When the mark 2 is scanned in the X-axis direction, only the reflected light obtained from the area illuminated in a converged state enters the range of the measurement NA of the objective lens 41, and the measurement light again passes through the aperture diaphragm 40, the λ/4 plate 39, and the PBS 38 and then is directed to the detector 44.

On the other hand, FIG. 11B shows a state where the collimated light is vertically directed onto the mark 2 segmented in the Y-axis direction and is reflected and diffracted therefrom to form reflected light and diffracted light. Light collimated by the collimator lens 36 passes through the cylindrical lens 37 and the objective lens 41 which are arranged to provide Koehler illumination on the wafer W, and the collimated light which is broad in the Y-axis direction is illuminated on the mark 2. Here, the reason why measurement light is measured by irradiating the mark 2 with broad light which is widely broad in the Y-axis direction instead of irradiating the mark 2 with spot light is as follows. Specifically, even if a WIS (Wafer Induced Shift) error occurs in measurement light obtained from the localized defects present on the mark 2, the influence of such WIS error is reduced by the averaging effect. In particular, in the present embodiment, the aperture diaphragm 40 is arranged between the objective lens 41 and the λ/4 plate 39, the shape of the aperture formed in the aperture diaphragm 40 is elliptical, and the opening dimension of the aperture diaphragm 40 in the Y-axis direction is smaller than that in the X-axis direction. Thus, ±first-order diffracted light which is generated on the positive and negative sides in the Y-axis direction is shielded by the aperture diaphragm 40, so that only reflected light is measured by the detector 44.

As described above, if the light intensity of measurement light obtained from the patterns (recesses) of the mark 2 is equivalent to the light intensity of measurement light generated from the area other than the patterns, a portion of measurement light generated from the patterns becomes diffracted light. Since the diffracted light is shielded by the aperture diaphragm 40, the light intensity of measurement light generated from the patterns is less than the light intensity of measurement light generated from the area other than the patterns. Consequently, as in the above embodiments, the contrast of measurement light is improved, which is advantageous for improving measurement accuracy.

While a description has been given in the above embodiments by taking an example of an exposure apparatus as a lithography apparatus, the lithography apparatus is not limited thereto but may be other lithography apparatus. For example, the lithography apparatus may be a lithography apparatus that writes on a substrate (sensitizer coated thereon) using a charged particle beam such as an electron beam or may also be an imprint apparatus that molds an imprint material on a substrate using a mold to thereby form a pattern on the substrate.

### (Article Manufacturing Method)

An article manufacturing method according to an embodiment of the present invention is preferred in manufacturing an article such as a micro device such as a semiconductor device or the like, an element or the like having a microstructure, or the like. The article manufacturing method may include a step of forming a pattern (e.g., latent image pattern) on an object (e.g., substrate on which a photosensitive material is coated) using the aforementioned lithography apparatus; and a step of processing (e.g., step of developing) the object on which the latent image pattern has been formed in the previous step. Furthermore, the article manufacturing method may include other known steps (oxidizing, film forming, vapor depositing, doping, flattening, etching, resist peeling, dicing, bonding, packaging, and the like). The device manufacturing method of this embodiment has an advantage, as compared with a conventional device manufacturing method, in at least one of performance, quality, productivity and production cost of a device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-102990 filed on May 19, 2014, which is hereby incorporated by reference herein in its entirety.

1. A detection apparatus that detects a mark with a periodic structure, the apparatus comprising:
an illumination optical system configured to irradiate light on the mark;
a light receiving optical system configured to receive a diffracted light from the mark when a relative position between the illumination optical system and the mark is changed in a measurement direction; and
a photodetector configured to detect the diffracted light from the light receiving optical system,
wherein a numerical aperture of the light receiving optical system in the measurement direction is larger than a numerical aperture of the light receiving optical system in a non-measurement direction in the plane on which the mark is formed.

2. The apparatus according to claim 1, wherein the light receiving optical system has an aperture diaphragm and the opening dimension of the aperture diaphragm in the non-measurement direction is smaller than the opening dimension of the aperture diaphragm in the measurement direction.

3. The apparatus according to claim 1, wherein the light receiving optical system has an optical element and the optical element has different outer shape size in the measurement direction and the non-measurement direction such that the numerical aperture of the light receiving optical system in the non-measurement direction is smaller than a numerical aperture of the light receiving optical system in the measurement direction.

4. The apparatus according to claim 3, wherein the optical element is a lens of which shape is different in the measurement direction and the non-measurement direction so as not to make the diffracted light in the non-measurement direction incident on the photodetector.

5. The apparatus according to claim 1, wherein the mark includes a plurality of line patterns, and the patterns are juxtaposed at the first pitch in the measurement direction and are segmented with the second pitch in the non-measurement direction.

6. The apparatus according to claim 5, wherein the line width of one area, which constitutes the pattern segmented in the non-measurement direction, in the non-measurement direction is less than three times of the minimum line width of the one area in the measurement direction.

7. The apparatus according to claim 6, wherein the irradiation area of the light irradiated on the mark in the measurement direction is smaller than the first pitch and the irradiation area of the light irradiated on the mark in the non-measurement direction is large enough to irradiate a plurality of the areas such that the diffracted light is generated from the mark in the non-measurement direction.

8. A lithography apparatus for forming a pattern on a substrate, the apparatus comprising:
a stage for holding a substrate; and
a detection apparatus that detects a mark which is formed on the substrate with the periodic structure, the apparatus comprising:
an illumination optical system configured to irradiate light on the mark;
a light receiving optical system configured to receive a diffracted light from the mark when a relative position between the illumination optical system and the mark is changed in a measurement direction; and
a photodetector configured to detect the diffracted light from the light receiving optical system,
wherein a numerical aperture of the light receiving optical system in the measurement direction is larger than a numerical aperture of the light receiving optical system in a non-measurement direction in the plane on which the mark is formed.

9. A method of manufacturing an article, the method comprising:
patterning a substrate using a lithography apparatus according to claim comprising:
a stage for holding a substrate; and
a detection apparatus that detects a mark which is formed on the substrate with the periodic structure, the apparatus comprising:
an illumination optical system configured to irradiate light on the mark;
a light receiving optical system configured to receive a diffracted light from the mark when a relative position between the illumination optical system and the mark is changed in a measurement direction; and
a photodetector configured to detect the diffracted light from the light receiving optical system,
wherein a numerical aperture of the light receiving optical system in the measurement direction is larger than a numerical aperture of the light receiving optical system in a non-measurement direction in the plane on which the mark is formed, and processing the patterned substrate to manufacture the article.
